(19) United States
(12) Patent Application Publication
(10) Pub. No.: US 2026/0098341 A1
(43) Pub. Date: Apr. 9, 2026

(54) SUBSTRATE PROCESSING APPARATUS

(71) Applicant: SAMSUNG ELECTRONICS CO., LTD., Suwon-si (KR)

(72) Inventors: Woohyun Kim, Suwon-si (KR); Woo-Hee Kim, Ansan-si (KR); Hakyoung Kim, Suwon-si (KR); Jeong-Min Lee, Ansan-si (KR); Wonsub Hwang, Suwon-si (KR); Mingeon Kim, Suwon-si (KR); Jiyoon Mun, Suwon-si (KR); Hakjong Yu, Suwon-si (KR); Joonmyeong Choi, Suwon-si (KR)

(73) Assignee: Industry-University Cooperation Foundation Hanyang University ERICA Campus, Ansan-si (KR)

(21) Appl. No.: 19/172,061

(22) Filed: Apr. 7, 2025

(30) Foreign Application Priority Data
Oct. 8, 2024 (KR) 10-2024-0136702

(51) Int. Cl. C23C 16/52; C23C 16/455

(52) U.S. Cl. CPC C23C 16/52; C23C 16/45544; C23C 16/45561

(57) ABSTRACT

A substrate processing apparatus includes a process chamber for processing a substrate, a canister comprising an accommodation space configured to hold a precursor gas, a carrier gas line connected to the canister and configured to allow a carrier gas to flow into the canister, a source gas line connecting the canister and the process chamber, wherein the source gas line is configured to transport a mixed gas comprising the carrier gas and the precursor gas, a first valve configured to selectively open and close the source gas line, a second valve configured to selectively open and close the carrier gas line, and a controller configured to control the first valve and the second valve such that the source gas line is closed and the carrier gas line is open over a same time period.

### CROSS-REFERENCE TO RELATED APPLICATION

This application claims priority to Korean Patent Application No. 10-2024-0136702, filed in the Korean Intellectual Property Office on Oct. 8, 2024, the entire contents of which are hereby incorporated by reference.

### BACKGROUND

In order to manufacture a semiconductor device, a series of processes, such as deposition, etching, patterning, etc. may be performed. Recently, as the integration density of semiconductor devices increases, patterns with fine and high aspect ratios are formed in the semiconductor manufacturing processes. Forming a thin film in these patterns requires step coverage and thickness uniformity that can satisfy the required specification or quality level.

To meet these requirements, the physical vapor deposition (PVD) or chemical vapor deposition (CVD), and also the atomic layer deposition (ALD) that forms thin films with atomic layer thickness have been developed.

Among them, the atomic layer deposition (ALD) supplies a precursor material, that is, a raw material for a thin film to the substrate in a gaseous state. To ensure the characteristics of the thin film deposited on the substrate, such as growth and quality of the film, it is necessary to stably supply the precursor gas.

### SUMMARY

In general, the present disclosure is directed toward a substrate processing apparatus capable of improving the characteristics of a thin film formed on a substrate, improve process uniformity by constantly adjusting the concentration of the precursor gas, prevent waste of precursor, and ensure a recharging period of the precursor to improve process efficiency.

According to some implementations, the present disclosure is directed to a substrate processing apparatus that includes a process chamber for processing a substrate, a canister comprising an accommodation space having a precursor gas, a carrier gas line connected to the canister and configured to allow a carrier gas to flow into the canister, a source gas line connecting the canister and the process chamber, wherein the source gas line is configured to transport a mixed gas comprising the carrier gas and the precursor gas, a first valve configured to selectively open and close the source gas line, a second valve configured to selectively open and close the carrier gas line, and a controller configured to control the first valve and the second valve such that the source gas line is closed and the carrier gas line is open over a same time period.

According to some implementations, the present disclosure is directed to a substrate processing apparatus that includes a carrier gas supply including a carrier gas box configured to store a carrier gas and a carrier gas line connected to the carrier gas box, the carrier gas line is configured to provide flow of the carrier gas, a precursor gas supply including a canister configured to generate a precursor gas, and a source gas line configured to provide flow of a mixed gas of the carrier gas and the precursor gas, the source gas line connecting the canister and the process chamber, and a valve on the source gas line and configured to control flow of the mixed gas to the process chamber.

According to some implementations, the present disclosure is directed to a substrate processing apparatus that includes a process chamber for processing a substrate, a carrier gas supply including a carrier gas box configured to store a carrier gas and a carrier gas line connected to the carrier gas box, the carrier gas line is configured to provide flow of the carrier gas, a precursor gas supply including a canister configured to generate a precursor gas, and a source gas line configured to provide flow of a mixed gas of the carrier gas and the precursor gas, wherein the source gas line connects the canister and the process chamber, a first valve configured to selectively open and close the source gas line, a second valve configured to selectively open and close the carrier gas line, a concentration sensor disposed on the source gas line and configured to measure a concentration of the mixed gas, and a controller configured to control the first valve or the second valve based on the concentration of the mixed gas measured by the concentration sensor, based on the concentration of the mixed gas being less than a set concentration, the controller is configured to control the second valve to open the carrier gas line.

### BRIEF DESCRIPTION OF THE DRAWINGS

Example implementations will be more clearly understood from the following detailed description, taken in conjunction with the drawings.

FIG. 1 is a diagram schematically illustrating an example of a substrate processing apparatus according to some implementations.

FIG. 2 is a diagram illustrating an example of a partial configuration of the substrate processing apparatus of FIG. 1 according to some implementations.

FIG. 3 is a control block diagram illustrating example configurations for controlling a substrate processing apparatus according to some implementations.

FIG. 4 is a flowchart illustrating an example of a substrate processing method of a substrate processing apparatus according to some implementations.

FIG. 5 is a diagram illustrating the substrate processing method of FIG. 4 according to some implementations.

FIG. 6 is a flowchart illustrating an example of a substrate processing method according to some implementations.

FIGS. 7 and 8 are timing diagrams illustrating an example of a gas supply timing for one cycle of substrate processing according to some implementations.

FIG. 9 is a flowchart illustrating an example of a substrate processing method according to some implementations.

FIGS. 10 to 12 are timing diagrams illustrating the substrate processing method of FIG. 9 according to some implementations.

FIG. 13 is a graph illustrating an example of a thin film density according to a flow rate and isolation time of a carrier gas according to some implementations.

FIG. 14 is a flowchart illustrating an example of a substrate processing method according to some implementations.

FIG. 15 is a diagram illustrating an example of a partial configuration of a substrate processing apparatus according to some implementations.

### DETAILED DESCRIPTION

Hereinafter, example implementations will be explained in detail with reference to the accompanying drawings.

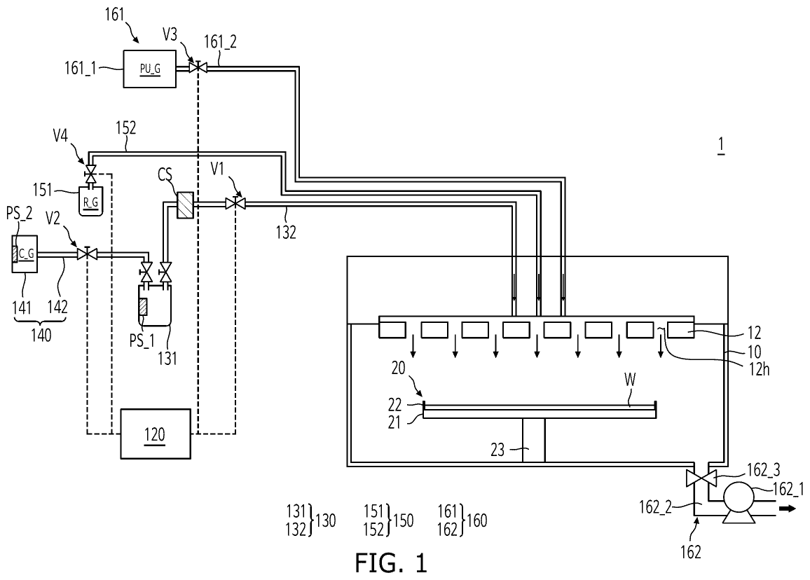

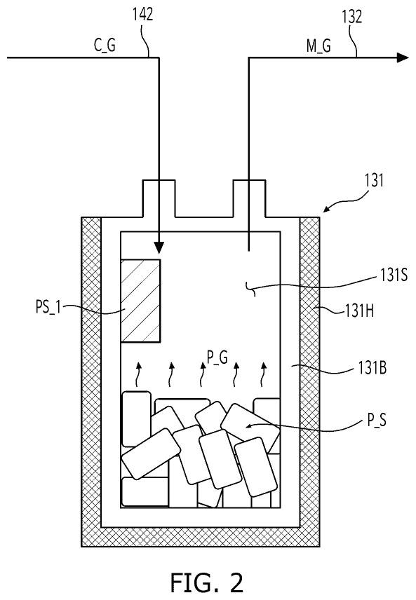

FIG. 1 is a diagram schematically illustrating an example of a substrate processing apparatus according to some implementations. FIG. 2 is a diagram illustrating an example of a partial configuration of the substrate processing apparatus of FIG. 1 according to some implementations.

In FIGS. 1 and 2, a substrate processing apparatus 1 may include a process chamber 10, a substrate supporter 20, a controller 120, a precursor gas supply 130, a carrier gas supply 140, a reactant gas supply 150, a purge device 160, and first to fourth valves V1 to V4.

The process chamber 10 may form a space for processing the substrate W. The process chamber 10 may provide a space for accommodating the substrate W and performing a deposition process. For example, deposition process may be performed in the process chamber 10. The deposition process may include, for example, chemical vapor deposition (CVD) and atomic layer deposition (ALD). In some implementations, deposition, etching, and cleaning may be performed together in the process chamber 100.

The substrate W may be an object on which a thin film including ruthenium (Ru), tantalum (Ta), tungsten (W), etc. is formed. The substrate W may be manufactured from, for example, a semiconductor wafer, such as a silicon wafer or a germanium wafer. The substrate W may be a silicon (Si) substrate, a silicon oxide (SiO₂) substrate, a TiN substrate, etc. However, the present disclosure are not limited thereto, and various materials may be included.

Various patterns may be formed on the substrate W. For example, a conductive layer or an electrode including a metal, a metal nitride, a metal silicide, or a metal oxide, or an insulating layer including silicon oxide or silicon nitride may be formed on the substrate W.

A shower head 12, the substrate supporter 20, and a purge discharge unit 162 may be provided inside the process chamber 10.

The shower head 12 may be disposed on an upper portion of the process chamber 10. The shower head 12 may be connected to the precursor gas supply 130, the carrier gas supply 140, the reactant gas supply 150, and the purge device 160, respectively. Specifically, the shower head 12 may be connected to a source gas line 132, a reactant gas line 152, and a purge gas line 161_2, respectively.

The shower head 12 may include a plurality of injection holes 12h for injecting various gases. The shower head 12 may supply through the injection hole 12h the precursor gas and the reactant gas as a thin film raw material gas, and supply the purge gas for purging into the process chamber 10.

The substrate supporter 20 may be provided inside the process chamber 10 as a susceptor on which the substrate W is loaded. One or a plurality of substrates W may be disposed on the substrate supporter 20.

The substrate supporter 20 may include a stage 21 that supports the substrate W. A heater may be provided within the stage 21. The heater may be connected to a heater power source and heat the substrate W to a predetermined temperature. For example, the heater may be heated in a temperature range of about 200° C. to 700° C. Coils may be arranged in a concentric circle. In addition, the stage 21 may further include an electrostatic electrode (not illustrated) for holding the substrate W on an upper portion thereof with an electrostatic adsorption force.

A rim 22 may be provided on the stage 21. The rim 22 may surround the substrate W placed on the stage 21. The rim 22 may prevent the substrate W from sliding on the stage 21. For example, the rim 22 may include a ceramic material.

The substrate supporter 20 may include an elevation device 23. The stage 21 may be installed to be moved up and down. The elevation device 23 may raise and lower the stage 21 in a vertical direction. In some implementations, the substrate supporter 20 may be rotatably installed.

The precursor gas supply 130 may be disposed outside the process chamber 10. The precursor gas supply 130 may include a canister 131 and the source gas line 132.

In FIG. 2, the canister 131 may include a body portion 131B forming an accommodation space 131S. The body portion 131B may have an approximately cylindrical shape, but is not limited thereto and may have various shapes.

The canister 131 may accommodate a precursor source in the accommodation space 131S. For example, the precursor source may include ruthenium (Ru), zirconium (Zr), hafnium (Hf), titanium (Ti), tantalum (Ta), aluminum (Al), etc. The precursor source may be a solid precursor P_S or a liquid precursor. In the accommodation space 131S, the solid precursor P_S may be sublimated or the liquid precursor may be vaporized to form a precursor gas P_G. In some implementations, if a liquid precursor is used, the canister 131 may be a bubbler.

The canister 131 may include a heater 131H for heating the precursor source. The heater 131H may facilitate the sublimation of the solid precursor P_S or the vaporization of the liquid precursor by heating the precursor source. The heater 131H may be disposed outside the body portion 131B. The heater 131H may surround the body portion 131B.

The canister 131 may receive a carrier gas C_G from the carrier gas supply 140. The canister 131 may be connected to a carrier gas line 142. The carrier gas C_G may be supplied to the accommodation space 131S of the canister 131. The carrier gas C_G may be mixed with the precursor gas P_G in the accommodation space 131S to form a mixed gas M_G.

The canister 131 may be connected to the source gas line 132 to allow the mixed gas M_G to be discharged from the accommodation space 131S. The mixed gas M_G of the carrier gas C_G and the precursor gas P_G may be discharged to the outside of the accommodation space 131S through the source gas line 132. The mixed gas M_G may flow along the source gas line 132 and be supplied into the process chamber 10. The mixed gas M_G may be supplied to the substrate W as a raw material for forming a thin film.

A first pressure sensor PS_1 may be disposed inside the canister 131. The first pressure sensor PS_1 may measure an internal pressure of the canister 131. That is, the first pressure sensor PS_1 may measure the pressure of the mixed gas M_G. The pressure data of the mixed gas M_G measured by the first pressure sensor PS_1 may be transmitted to the controller 120.

In FIG. 1, the source gas line 132 may connect the canister 131 and the process chamber 10. The mixed gas M_G may flow through the source gas line 132. The mixed gas M_G may flow to the shower head 12 through the source gas line 132. The mixed gas M_G may be injected to the substrate W through the shower head 12.

A concentration sensor CS may be disposed on the source gas line 132. The concentration sensor CS may measure the precursor concentration of the mixed gas M_G. The concentration sensor CS may measure the concentration of the mixed gas M_G according to the Beer-Lambert Law. For example, the concentration sensor CS may be a Non-Dispersive Infrared (NDIR) sensor, but is not limited thereto.

A first valve V1 may be provided on the source gas line 132. The first valve V1 may selectively open and close the source gas line 132. The first valve V1 may control the flow of the mixed gas M_G flowing inside the source gas line 132. If the first valve V1 opens the source gas line 132, the mixed gas M_G may flow from the canister 131 to the process chamber 10. If the first valve V1 closes the source gas line 132, the mixed gas M_G may be blocked from flowing from the canister 131 to the process chamber 10.

The carrier gas supply 140 may be disposed outside the process chamber 10. The carrier gas supply 140 may be connected to the precursor gas supply 130. The carrier gas supply 140 may include a carrier gas box 141 and the carrier gas line 142.

The carrier gas box 141 may store the carrier gas C_G. The carrier gas C_G may carry the precursor gas P_G. That is, the precursor gas P_G may be transported to the process chamber 10 by the carrier gas C_G. The carrier gas C_G may be a gas having low reactivity.

The examples may include nitrogen (N₂), argon (Ar), neon (Ne), helium (He), carbon dioxide (CO₂), etc.

A second pressure sensor PS_2 may be provided inside the carrier gas box 141. The second pressure sensor PS_2 may measure the internal pressure of the carrier gas box 141. That is, the second pressure sensor PS_2 may measure the pressure of the carrier gas C_G present in the carrier gas box 141. The pressure data of the carrier gas C_G measured by the second pressure sensor PS_2 may be transmitted to the controller 120.

The carrier gas line 142 may connect the carrier gas box 141 and the canister 131. The carrier gas C_G stored in the carrier gas box 141 may flow to the canister 131 through the carrier gas line 142.

A second valve V2 may be provided on the carrier gas line 142. The second valve V2 may selectively open and close the carrier gas line 142. The second valve V2 may control the flow of the carrier gas C_G flowing inside the carrier gas line 142. If the second valve V2 opens the carrier gas line 142, the carrier gas C_G may flow from the carrier gas box 141 to the canister 131. If the second valve V2 closes the carrier gas line 142, the carrier gas C_G may be blocked from flowing from the carrier gas box 141 to the canister 131.

The purge device 160 may include a purge gas supply 161 and the purge discharge unit 162.

The purge gas supply 161 may include a purge gas box 161_1 that stores a purge gas PU_G, and a purge lath line 161_2 that connects the purge gas box 161_1 and the process chamber 10.

The purge gas box 161_1 may store the purge gas PU_G. For example, the purge gas PU_G may include nitrogen (N₂), argon (Ar), helium (He), etc. The purge gas PU_G may be supplied into the process chamber 10 for purging.

The purge gas line 161_2 may connect the purge gas box 161_1 and the process chamber 10. The purge gas PU_G stored in the purge gas box 161_1 may flow to the process chamber 10 through the purge gas line 161_2. The purge gas PU_G may flow to the shower head 12 through the purge gas line 161_2. The purge gas PU_G may be injected into the process chamber 10 through the shower head 12.

A third valve V3 may be provided on the purge gas line 161_2. The third valve V3 may selectively open and close the purge gas line 161_2. The third valve V3 may control the flow of the purge gas PU_G flowing inside the purge gas line 161_2. If the third valve V3 opens the purge gas line 161_2, the purge gas PU_G may flow from the purge gas box 161_1 to the process chamber 10. If the third valve V3 closes the purge gas line 161_2, the purge gas PU_G may be blocked from flowing from the purge gas box 161_1 to the process chamber 10.

The purge discharge unit 162 may include a purge pump 162_1, a purge discharge line 162_2, and a purge valve 162_3. The purge pump 162_1 may discharge gas from inside the process chamber 10. The purge pump 162_1 may discharge the purge gas PU_G supplied from the purge gas supply 161 into the process chamber 10, and a precursor material or a reactant material not deposited on the substrate W. In some implementations, ligands separated from the precursor material may be discharged together. The purge discharge line 162_2 may be a path through which the gas inside the process chamber 10 is discharged. The purge valve 162_3 may be disposed on the purge discharge line 162_2 to selectively open and close the purge discharge line 162_2. If the purge pump 162_1 is operated while the purge discharge line 162_2 is opened by the purge valve 162_3, the gas inside the process chamber 10 may be discharged through the purge discharge line 162_2.

The reactant gas supply 150 may include a reactant gas box 151 and the reactant gas line 152.

The reactant gas box 151 may store reactant gas R_G. The reactant gas R_G may be a raw material for the thin film to be formed on the substrate W. For example, the reactant gas R_G may include oxygen (O₂), ozone (O₃), water vapor (H₂O), hydrogen peroxide (H₂O₂), B₂H₆, Si₂H₆, SiH₄, H₂, etc.

The reactant gas line 152 may connect the reactant gas box 151 and the process chamber 10. The reactant gas R_G stored in the reactant gas box 151 may flow to the process chamber 10 through the reactant gas line 152. The reactant gas R_G may flow to the shower head 12 through the reactant gas line 152. The reactant gas R_G may be injected to the substrate W through the shower head 12.

A fourth valve V4 may be provided on the reactant gas line 152. The fourth valve V4 may selectively open and close the reactant gas line 152. The fourth valve V4 may control the flow of the reactant gas R_G flowing inside the reactant gas line 152. If the fourth valve V4 opens the reactant gas line 152, the reactant gas R_G may flow from the reactant gas box 151 to the canister 131. If the fourth valve V4 closes the reactant gas line 152, the reactant gas R_G may be blocked from flowing from the reactant gas box 151 to the canister 131.

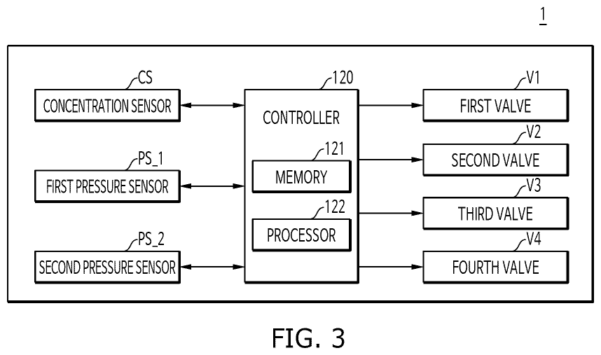

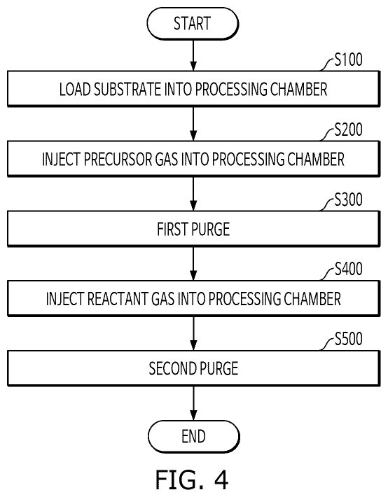

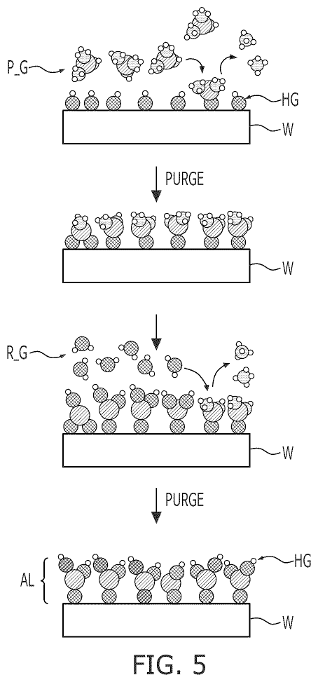

FIG. 3 is a control block diagram illustrating example configurations for controlling a substrate processing apparatus according to some implementations. FIG. 4 is a flowchart illustrating an example of a substrate processing method of a substrate processing apparatus according to some implementations. FIG. 5 is a diagram illustrating the substrate processing method of FIG. 4 according to some implementations.

In FIG. 3, the substrate processing apparatus 1 may include the concentration sensor CS, the first pressure sensor PS_1, the second pressure sensor PS_2, the controller 120, and the first to fourth valves V1 to V4.

The concentration sensor CS may be disposed on the source gas line. The concentration sensor CS may measure the precursor concentration of the mixed gas flowing inside the source gas line. The concentration data of the mixed gas measured by the concentration sensor CS may be transmitted to the controller 120.

The first pressure sensor PS_1 may be disposed inside the canister 131. That is, the first pressure sensor PS_1 may be disposed in the accommodation space 131S. The first pressure sensor PS_1 may measure the internal pressure of the canister 131. The first pressure sensor PS_1 may measure the pressure of the mixed gas. The pressure of the mixed gas may be defined as the sum of the pressure of the precursor gas and the pressure of the carrier gas. For example, the precursor gas may be a precursor gas sublimated from the solid precursor or a precursor gas vaporized from the liquid precursor.

The second pressure sensor PS_2 may be disposed inside the carrier gas box 141. The second pressure sensor PS_2 may measure the internal pressure of the carrier gas box 141. The second pressure sensor PS_2 may measure the pressure of the carrier gas.

The pressure data measured from the first pressure sensor PS_1 and the second pressure sensor PS_2 may be transmitted to the controller 120. The controller 120 may control the first valve V1 and the second valve V2 based on the pressure data measured by the first pressure sensor PS_1 and the second pressure sensor PS_2. The controller 120 may calculate a ratio of the pressure of the precursor gas and the pressure of the mixed gas from the pressure of the mixed gas measured by the first pressure sensor PS_1 and the pressure of the carrier gas measured by the second pressure sensor PS_2. In this way, the controller 120 may obtain the saturation concentration of the precursor gas.

In some implementations, the controller 120 may calculate the saturation concentration of the precursor gas based on a value obtained by converting the flow rate of the carrier gas into pressure, and on a vapor pressure of the precursor source according to the temperature inside the canister.

The substrate processing apparatus 1 may include an input interface for receiving a control signal to the controller 120. The input interface may receive a control command from a user. That is, the input interface may receive a command for controlling a component of the substrate processing apparatus 1. For example, a signal for controlling the first to fourth valves V1 to V4 to be opened or locked may be input through the input interface.

The controller 120 controlling the component of the substrate processing apparatus may include all of directly transmitting a control signal to the corresponding component, transmitting a control signal to a separate driving device driving the corresponding component, and transmitting a control signal to another intermediate component required to control the corresponding component.

The controller 120 may include a memory 121 that stores a program and various types of data for executing the operations already described above or will be described below, and a processor 122 that processes data by executing the program stored in the memory 121.

The memory 121 may include at least one of a volatile memory, such as a static random access memory (SRAM), a dynamic random access memory (DRAM), etc., and a non-volatile memory such as a flash memory, a read only memory (ROM), an erasable programmable read only memory (EPROM), an electrically erasable programmable read only memory (EPROM), etc.

The non-volatile memory may operate as an auxiliary memory device of the volatile memory, and retain stored data even if the power of the substrate processing apparatus is interrupted. For example, the non-volatile memory may store a control program and control data for controlling the operation of the substrate processing apparatus.

Unlike the non-volatile memory, the volatile memory may lose stored data when power of the substrate processing apparatus is interrupted. The volatile memory may load a control program and control data from the non-volatile memory and temporarily store the control program and the control data, temporarily store an input setting value or control command, or temporarily store a control signal, etc. output from the processor 122.

The memory 121 may store the vapor pressure data of the precursor source according to temperature, the pressure data according to the flow rate of the carrier gas, etc. The processor 122 may process data or output a control signal according to the program stored in the memory 121. For example, the processor 122 may process data or output control signals according to the program stored in the memory 121 which includes instructions for executing operations of the substrate processing apparatus or the substrate processing method.

The processor 122 and the memory 121 may be provided in a single configuration or may be provided in a plurality of configurations according to their capacities. In addition, the processor 122 and the memory 121 may be physically separated or may be provided as a single chip.

Hereinafter, a method for controlling the components of the substrate processing apparatus executed by the controller 120 or the processor 122 will be described in detail.

In FIGS. 4 and 5, the substrate processing method according to some example embodiments may include first to fifth operations S100 to S500. The drawings illustrated in FIG. 5 may correspond to the second to fifth operations S200 to S500, respectively.

The substrate may be loaded into the process chamber 10, at S100. The substrate W may be seated on the substrate supporter. A plurality of substrates W may be provided. Dangling bonds may be formed on a surface of the substrate W, and the surface of the substrate W may have high surface energy. A hydroxyl group (—OH) (HG) may be bonded to the dangling bonds formed on the surface of the substrate W.

After the substrate is loaded, the precursor gas may be injected into the process chamber, at S200. The precursor gas P_G may be mixed with the carrier gas and supplied in the form of a mixed gas. The mixed gas may be supplied by the precursor gas supply and the carrier gas supply. The mixed gas may be supplied into the process chamber through the shower head. The precursor gas P_G may be a precursor that provides a material that forms a thin film. Some ligands of the precursor gas P_G may be bonded to the hydroxyl group (HG) on the substrate W. For example, the precursor gas P_G may be trimethylaluminum (TMA) (Al(CH₃)₃). The CH3⁻ ligands of the precursor gas P_G may bond with the hydrogen atoms of the hydroxyl group (HG), generating CH₃⁺ and CH₄ gases.

The precursor gas P_G may be supplied in pulses for a predetermined time. The precursor gas P_G may be injected onto the substrate W through the shower head. When it is stated that the precursor gas P_G is supplied in pulses for a predetermined time, it may mean that the gas is supplied at a constant flow rate for the predetermined time and then blocked, and may be understood in the same sense below.

After the precursor gas is injected, first purge may be performed, at S300. The purge gas injection unit may inject the purge gas into the process chamber. The precursor gas not deposited on the substrate W, or newly generated gas, etc. may be discharged to the purge discharge unit by the first purge. For example, remaining TMA and methane (CH₄) gases may be discharged. The purge gas may be supplied in pulses for a predetermined time. The first purge gas may include nitrogen (N₂), argon (Ar), helium (He), etc. Once the first purge is complete, only the precursor gas may be adsorbed on the substrate W.

After the first purge, the reactant gas may be injected into the process chamber, at S400. The reactant gas may be supplied by the reactant gas supply. The reactant gas R_G may be supplied into the process chamber through the shower head. The reactant gas R_G may be a raw material that forms a thin film. For example, the reactant gas R_G may be water vapor (H₂O). The water vapor (H₂O) may bond with the precursor. The hydrogen atoms of the water vapor (H₂O) may bond with the remaining ligands of TMA to produce methane (CH₄) gas.

After the reactant gas is injected, the second purge may be performed, at S500. The purge gas injection unit may inject the purge gas into the process chamber. The reactant gas R_G not deposited on the substrate W, or newly generated gas, etc. may be discharged to the purge discharge unit by the second purge. For example, remaining water vapor and methane (CH₄) gas may be discharged. The purge gas may be supplied in pulses for a predetermined time. The second purge gas may include nitrogen (N₂), argon (Ar), helium (He), etc. Once the second purge is complete, the precursor gas and the reactant gas may be adsorbed on the substrate W to form an atomic layer AL. For example, an aluminum oxide layer may be formed on the substrate W.

The second to fifth operations S200 to S500 form one cycle, and the cycle may be repeat according to required characteristics of the thin film. If a thin film having a desired thickness is formed, the substrate W may be cooled and the substrate may be unloaded from the process chamber 10.

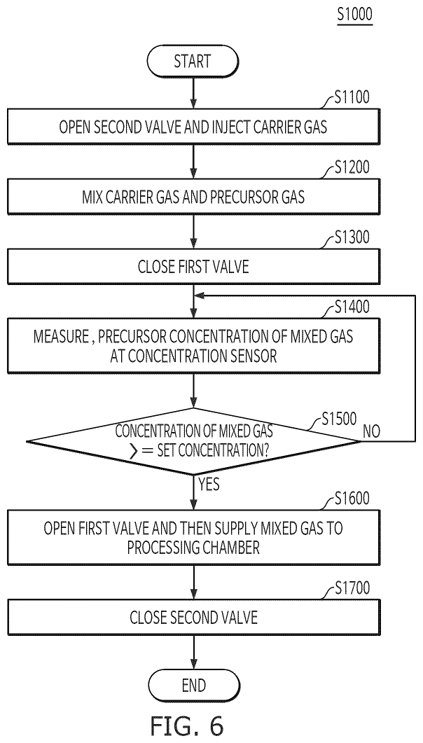

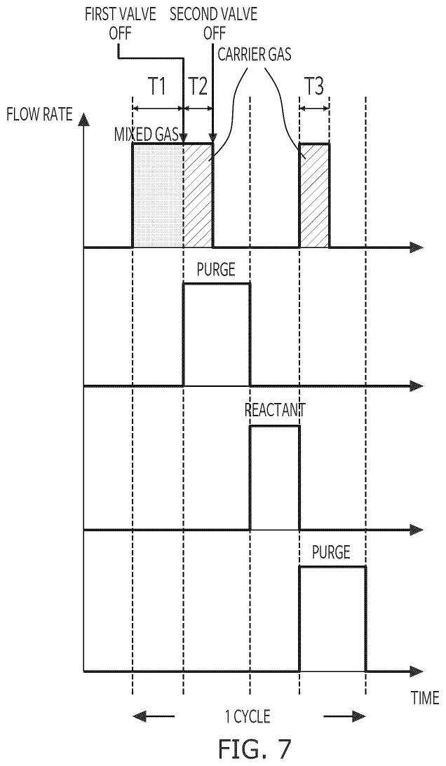

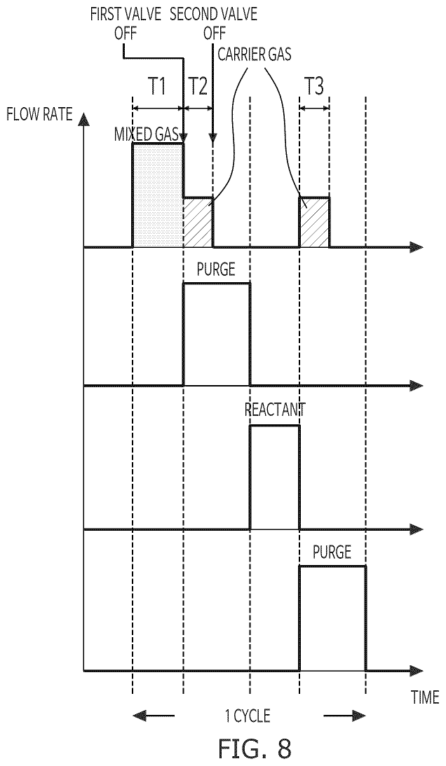

FIG. 6 is a flowchart illustrating an example of a substrate processing method according to some implementations. FIGS. 7 and 8 are timing diagrams illustrating an example of a gas supply timing for one cycle of substrate processing according to some implementations.

In FIG. 6, a substrate processing method S1000 may include first to seventh operations S1100 to S1700. For example, the substrate processing method S1000 may be a certain step of the thin film deposition method.

The method S1000 may include opening the second valve and injecting the carrier gas, at S1100. The second valve may be opened and the carrier gas may be injected into the canister. A solid precursor or a liquid precursor may be accommodated inside the canister. The precursor gas may be present inside the canister. For example, the precursor gas may be sublimated from the solid precursor or vaporized from the liquid precursor.

The method S1000 may include mixing the carrier gas and the precursor gas, at S1200.

The carrier gas may be mixed with the precursor gas inside the canister. The carrier gas flowing through the inside of the canister may flow to the source gas line. In this case, the carrier gas may carry a portion of the precursor gas. The mixed gas may be supplied into the process chamber along the source gas line. The precursor gas present in the mixed gas may be injected onto the substrate and deposited on the substrate.

The method S1000 may include closing the first valve, at S1300.

The controller may control so that the first valve may be closed, thereby closing the source gas line. The controller may control so that the first valve closes the source gas line while the carrier gas line is opened by the second valve. The carrier gas may be injected into the canister and diffused for sufficient time. The carrier gas may be sufficiently mixed with the precursor gas generated in the canister. The controller may prevent the mixed gas from flowing into the process chamber along the source gas line. Since the mixed gas is prevented from flowing into the process chamber, it may sufficiently diffuse in the canister and the source gas line.

The method S1000 may include measuring, at a concentration sensor, the precursor concentration of the mixed gas, at S1400.

The mixed gas may flow through the source gas line. A concentration sensor may be disposed on the source gas line. The concentration sensor may measure the precursor concentration of the mixed gas. The concentration sensor may transmit the measured concentration data of the mixed gas to the controller.

The method S1000 may include comparing the concentration of the mixed gas with a set concentration, at S1500.

The controller may compare the concentration data of the mixed gas received from the concentration sensor with the set concentration. For example, the set concentration may be the concentration of the mixed gas when the carrier gas is argon (Ar) and the carrier gas is supplied at a flow rate of 300 sccm. However, this is only an example, and it may be variously changed according to a substrate treatment environment, a process recipe, etc.

The controller may control such that the sixth operation S1600 is performed if the concentration of the mixed gas is higher than or equal to the set concentration, and control such that the fourth operation S1400 is performed after a predetermined time elapses, if the concentration of the mixed gas is lower than the set concentration. That is, if the concentration of the mixed gas is lower than the set concentration, the controller may induce additional supply of the carrier gas by controlling the open state of the second valve to be maintained for a predetermined time.

The method S1000 may include opening the first valve and then supplying the mixed gas to the process chamber, at S1600.

If the concentration of the mixed gas is higher than or equal to the set concentration, the controller may open the first valve and then supply the mixed gas to the process chamber. Since the precursor concentration of the mixed gas at or above the set concentration level is secured, it may be injected into the process chamber and the process may proceed.

The method S1000 may include closing the second valve, at S1700. The controller may close the second valve to close the carrier gas line. By closing the second valve, it is possible to block the carrier gas from being supplied to the canister.

In FIGS. 7 and 8, for one cycle of substrate processing, supplying the mixed gas, supplying the purge gas, supplying the reactant gas supply, and supplying the purge gas may be sequentially performed. In this way, by executing one cycle, one layer may be deposited according to the atomic layer deposition method.

A first time T1 may correspond to the operation of supplying the mixed gas. For the first time T1, the second valve opens the carrier gas line, allowing the carrier gas to be supplied to the canister for the first time T1. For the first time T1, the first valve of the substrate processing apparatus may be in open state. The carrier gas may be mixed with the precursor gas inside the canister and supplied to the process chamber.

After the first time T1 elapses, the first valve may be closed, thus closing the source gas line. In this case, since the second valve is opened, the carrier gas may be further injected into the canister. The second valve may be further opened for a second time T2. The second time T2 may correspond to a purge operation. The carrier gas may be further injected into the carrier gas for the second time T2. Since the first valve is closed, the carrier gas may be additionally supplied to the canister and sufficiently diffused inside the canister. The precursor gas is generated inside the canister, and the generated precursor gas and the carrier gas may be mixed and move to a part of the source gas line. Specifically, the mixed gas may be moved to a point where the first valve is disposed.

A concentration sensor may be disposed on the source gas line. The concentration sensor may measure the concentration of the mixed gas and transmit the measured concentration to the controller. In response to determining that the concentration of the mixed gas measured by the concentration sensor is less than the set concentration, the controller may control so that the second valve opens the carrier gas line for a third time T3. The third time T3 may correspond to a second purge operation (i.e., a purge operation after the reactant gas injection operation). However, the present disclosure are not limited thereto. In some implementations, the third time T3 may correspond to the first purge operation (i.e., the purge operation after the mixed gas supply operation) or the reactant gas injection operation. That is, the third time T3 may be performed within a unit cycle of the thin film deposition method. In addition, he third time T3 may correspond to a plurality of operations. For example, the third time T3 may at least partially correspond to the reactant gas injection operation and the second purge operation. The second valve may open the carrier gas line for the third time T3, allowing for additional supply of the carrier gas. Since the first valve is closed for the third time T3, the precursor concentration may be increased as the carrier gas is additionally supplied.

In response to determining that the concentration of the mixed gas measured by the concentration sensor is greater than or equal to the set concentration, the controller may control so that the second valve maintains the closed state. That is, if the concentration of the mixed gas is sufficiently high, the controller may not additionally supply the carrier gas for the third time T3.

In FIG. 7, the flow rate of the carrier gas supplied for the second In FIG. 8, the flow rate of the carrier gas supplied for the second time T2 and the third time T3 may be less than the flow rate of the carrier gas supplied for the first time T1. If the concentration of the mixed gas is less than the set concentration, the additionally supplied carrier gas may be supplied at a lower flow rate.

Hereinafter, a process of performing the atomic layer deposition method together with the operation of the first to fourth valves will be described.

The controller may open the second valve to inject the carrier gas into the canister. The controller may control the second valve to close the carrier gas line upon lapse of a second time T2 during which the carrier gas and the precursor gas are mixed. The second valve may be opened for the second time T2, allowing the carrier gas to be injected into the canister. The carrier gas may be mixed with the precursor gas and injected into the process chamber along the source gas line. For the first time T1, the mixed gas may be supplied to the process chamber and then the first valve may be closed. As the first valve is closed, the mixed gas may not be supplied to the process chamber along the source gas line and may be isolated up to the point where the first valve is installed. Since the second valve is opened while the first valve is closed, the carrier gas may be additionally injected into the canister.

After the injection of the mixed gas is complete, the first purge may start. The third valve may open simultaneously with the closure of the first valve, allowing the purge gas to be supplied into the process chamber. The purge gas may cause residual gas such as unreacted precursor gas or ligands inside the chamber to the outside of the process chamber through the purge discharge unit. The purge gas may be supplied in pulses while the third valve is open for a predetermined time. The third valve may be open for the predetermined time and then closed. The fourth valve may be opened simultaneously with the closure of the third valve.

When the fourth valve is opened, the reactant gas may be injected into the process chamber. The reactant gas may be combined with the precursor material on the substrate to form an atomic layer. The fourth valve may be supplied in pulses. The fourth valve may be open for a predetermined time and then closed.

After the injection of the reactant gas is complete, the second purge may begin. The third valve may open simultaneously with the closure of the fourth valve, allowing the purge gas to be supplied into the process chamber. The purge gas may discharge the residual gas such as unreacted reactant gas inside the chamber to the outside of the process chamber through the purge discharge unit. The purge gas may be supplied in pulses while the third valve is open for a predetermined time. The third valve may be open for the predetermined time and then closed.

After the second purge is complete, the next cycle of the atomic layer deposition method may proceed. The atomic layer deposition method may be performed several times in consideration of characteristics such as the thickness of the thin film to be deposited.

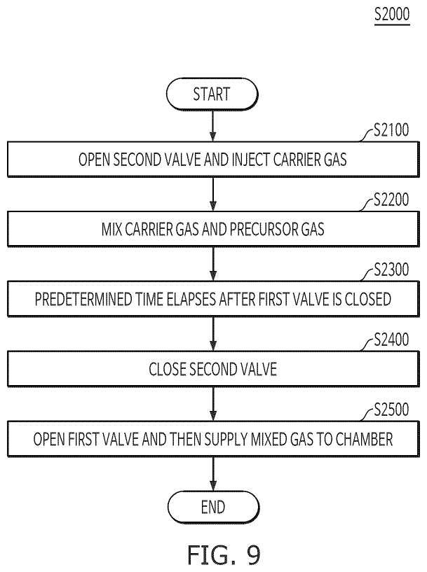

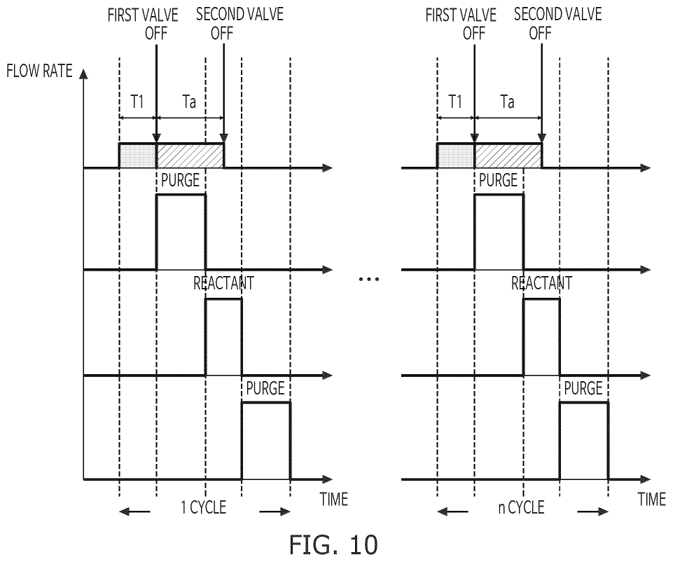

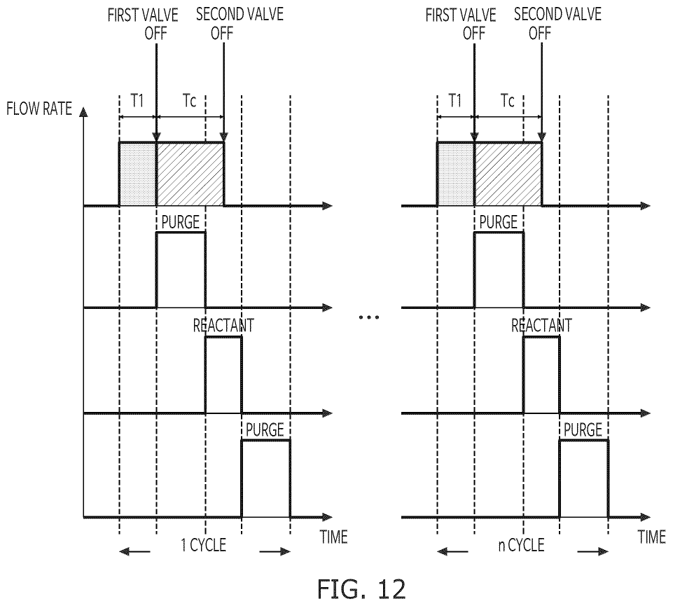

FIG. 9 is a flowchart illustrating an example of a substrate processing method according to some implementations. FIGS. 10 to 12 are timing diagrams illustrating the substrate processing method of FIG. 9 according to some implementations.

In FIG. 9, a substrate processing method S2000 may include first to seventh operations S2100 to S2500.

The method S2000 may include opening the second valve and injecting the carrier gas, at S2100. The second valve may be opened and the carrier gas may be injected into the canister. A solid precursor or a liquid precursor may be accommodated inside the canister. The precursor gas may be present inside the canister. For example, the precursor gas may be sublimated from the solid precursor or vaporized from the liquid precursor.

The method S2000 may include mixing the carrier gas and the precursor gas, at S2200.

The carrier gas may be mixed with the precursor gas inside the canister. The carrier gas flowing through the inside of the canister may flow to the source gas line. In this case, the carrier gas may carry a portion of the precursor gas. The mixed gas may be supplied into the process chamber along the source gas line. The precursor gas present in the mixed gas may be injected onto the substrate and deposited on the substrate.

The method S2000 may include allowing a predetermined time to elapse after closing the first valve, at S2300.

The controller may control so that the first valve is closed, thereby closing the source gas line. The carrier gas may be injected into the canister and diffused for sufficient time. The carrier gas may be sufficiently mixed with the precursor gas generated in the canister. The controller may prevent the mixed gas from flowing into the process chamber along the source gas line. Since the mixed gas is prevented from flowing into the process chamber, it may sufficiently diffuse in the canister and the source gas line.

The flow rate of the carrier gas supplied for the predetermined time may be lower than the flow rate of the carrier gas corresponding to the set concentration of FIG. 7. Even if the flow rate of the carrier gas is low, the concentration of the precursor gas may be secured at the set concentration level if sufficient time is given for the carrier gas to diffuse inside the canister.

In FIGS. 10 to 12, the second valve may open the carrier gas line and the carrier gas may be supplied to the canister for the first time T1. After the first time T1 elapses, the first valve may be closed, thus closing the source gas line. In this case, since the second valve is opened, the carrier gas may be further injected into the canister.

The second valve may be further opened for a predetermined time. The carrier gas may be further injected into the carrier gas for the predetermined time. Since the second valve is closed, the carrier gas may be additionally supplied to the canister and sufficiently diffused inside the canister. The precursor gas is generated inside the canister, and the generated precursor gas and the carrier gas may be mixed and move to a part of the source gas line. Specifically, the mixed gas may be moved to a point where the first valve is disposed.

The method S2000 may include closing the second valve, at S2400. The controller may close the second valve to close the carrier gas line. By closing the second valve, it is possible to block the carrier gas from being supplied to the canister. If the second valve is closed while the first valve is closed, the mixed gas may be isolated in the canister and a portion of the source gas line. The mixed gas may be sufficiently diffused while in an isolated state.

The method S2000 may include opening the first valve and then supplying the mixed gas to the process chamber, at S2500. If the concentration of the mixed gas is higher than or equal to the set concentration, the controller may open the first valve and then supply the mixed gas to the process chamber. The first valve may be opened and the second valve may also be opened. The second valve may be opened and the carrier gas may be supplied to the canister. That is, the carrier gas may become a mixed gas that carries the precursor gas. The mixed gas may be supplied into the process chamber through the source gas line. Since the precursor concentration of the mixed gas at or above the set concentration level is secured, it may be injected into the process chamber and the process may proceed.

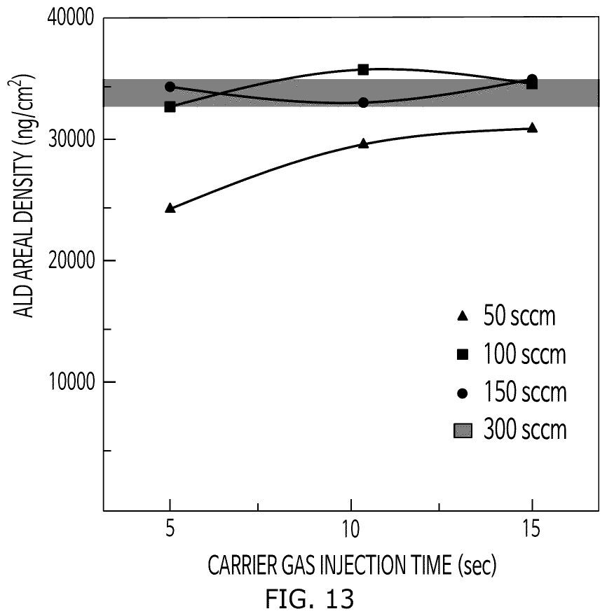

FIGS. 10 to 12 are timing diagrams illustrating an example of a thin film deposition method according to some implementations when the carrier gas is injected at different flow rates for a predetermined time. FIG. 13 is a graph illustrating an example of a thin film density according to a flow rate and isolation time of the carrier gas according to some implementations. For example, FIGS. 10 to 12 show that the carrier gas is injected at a flow rate of 50 sccm, 100 sccm, and 150 sccm, respectively.

In FIGS. 10 and 13, the carrier gas may be injected at the flow rate of 50 sccm and the first valve may be closed to isolate the mixed gas for a time Ta. For example, the time Ta may be 15 seconds. Specifically, after injecting the carrier gas at the flow rate of 50 sccm for 15 seconds, the first valve may be closed to isolate the carrier gas. In this case, for example, the characteristics of the thin film may be secured similarly to those achieved by injecting the carrier gas at a flow rate of 300 sccm without isolation.

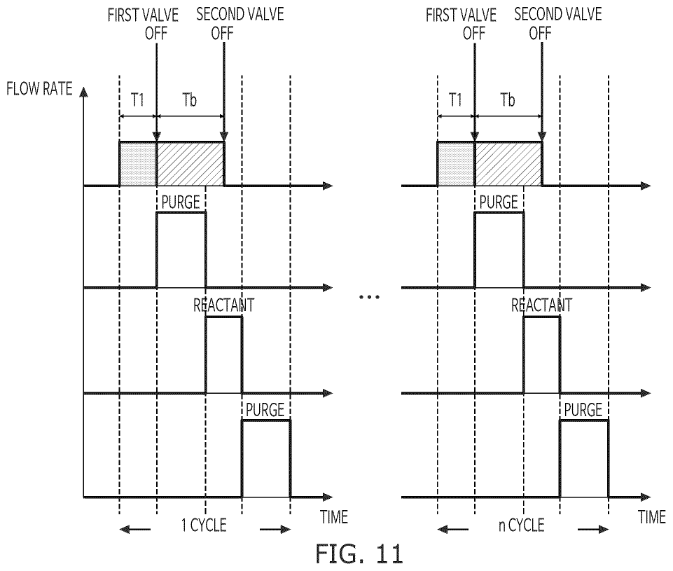

In FIGS. 11 and 13, the carrier gas may be injected at a flow rate of 100 sccm and the first valve may be closed to isolate the mixed gas for a time Tb. For example, the time Tb may be 10 seconds. Specifically, after injecting the carrier gas at a flow rate of 100 sccm for 10 seconds, the first valve may be closed to isolate the carrier gas. In this case, for example, the characteristics of the thin film may be secured similarly to those achieved by injecting the carrier gas at a flow rate of 300 sccm without isolation.

In FIGS. 11 and 13, the carrier gas may be injected at a flow rate of 150 sccm and the first valve may be closed to isolate the mixed gas for a time Tc. For example, the time Tc may be 5 seconds. Specifically, after injecting the carrier gas at a flow rate of 150 sccm for 5 seconds, the first valve may be closed to isolate the carrier gas. In this case, for example, the characteristics of the thin film may be secured similarly to those achieved by injecting the carrier gas at a flow rate of 300 sccm without isolation.

Hereinafter, differences from the substrate processing method according to the implementations illustrated in FIGS. 6 and 9 will be described. Elements that are similar to those already described above may be given the same reference numerals, and detailed description thereof may be omitted.

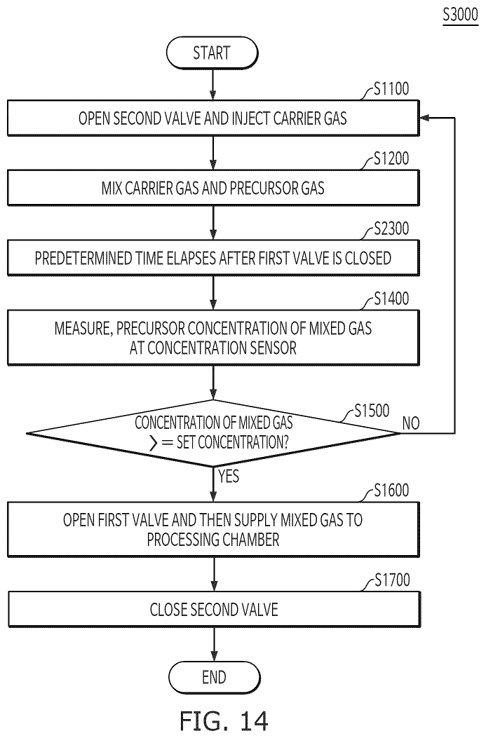

FIG. 14 is a flowchart illustrating an example of a substrate processing method according to some implementations. In FIG. 14, the substrate processing method S3000 may include allowing a predetermined time to elapse after closing the first valve, at S2300.

The controller may allow a predetermined time to elapse after the first valve is closed to close the source gas line. While isolated in the canister and the source gas line, the mixed gas may be sufficiently diffused. However, the concentration of the mixed gas may be less than the set concentration even after the predetermined time elapses. Accordingly, after allowing (S2300) the predetermined time to elapse after the first valve is closed, the substrate processing method S3000 may include measuring, at the concentration sensor, the precursor concentration of the mixed gas, at S1400.

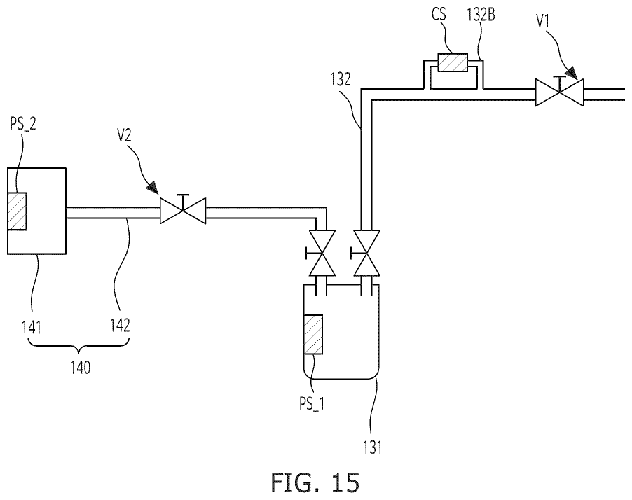

FIG. 15 is a diagram illustrating an example of a partial configuration of a substrate processing apparatus according to some implementations. In FIG. 15, the substrate processing apparatus may include a bypass line 132B.

The source gas line 132 may include the bypass line 132B. The bypass line 132B may be provided on the source gas line 132. Part of the mixed gas flowing through the source gas line 132 may flow along the bypass line 132B. The bypass line 132B may be provided to allow the part of the mixed gas to flow through for measurement of the concentration of the mixed gas.

The bypass line 132B may be disposed between the first valve V1 and the canister 131. The concentration sensor CS may be provided on the bypass line 132B. The concentration sensor CS may measure the concentration of the mixed gas flowing inside the bypass line 132B. The concentration sensor CS may transmit the concentration data of the mixed gas flowing inside the bypass line 132B to the controller.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A substrate processing apparatus, comprising:
a process chamber for processing a substrate;
a canister comprising an accommodation space configured to hold a precursor gas;
a carrier gas line connected to the canister and configured to allow a carrier gas to flow into the canister;
a source gas line connecting the canister and the process chamber, wherein the source gas line is configured to transport a mixed gas comprising the carrier gas and the precursor gas;
a first valve configured to selectively open and close the source gas line;
a second valve configured to selectively open and close the carrier gas line; and
a controller configured to control the first valve and the second valve such that the source gas line is closed and the carrier gas line is open over a same time period.

2. The substrate processing apparatus according to claim 1, wherein the controller is configured to control the second valve to open the carrier gas line for a first time period, and
wherein the controller is configured to control the first valve to close the source gas line subsequent to the first time period.

3. The substrate processing apparatus according to claim 2, wherein the controller is configured to control the second valve to close the carrier gas line after a second time period during which the carrier gas and the precursor gas are mixed, subsequent to the first valve closing the source gas line.

4. The substrate processing apparatus according to claim 1, further comprising:
a concentration sensor on the source gas line and configured to measure a concentration of the mixed gas in the source gas line,
wherein the controller is configured to control the first valve and the second valve based on the concentration of the mixed gas.

5. The substrate processing apparatus according to claim 4, wherein, based on the concentration of the mixed gas being less than a set concentration, the controller is configured to control the second valve to open the carrier gas line for a third time.

6. The substrate processing apparatus according to claim 4, wherein, based on the concentration of the mixed gas being greater than or equal to a set concentration, the controller is configured to control the first valve to open the source gas line.

7. The substrate processing apparatus according to claim 4,
wherein the source gas line further includes a bypass line configured to transport a portion of the mixed gas flows, and
wherein the concentration sensor is on the bypass line.

8. The substrate processing apparatus according to claim 4, further comprising:
a purge gas supply including a purge gas line connected to the process chamber, the purge gas line configured to provide flow of a purge gas;
a purge discharge unit configured to discharge a gas inside the process chamber; and
a third valve configured to selectively open and close the purge gas line,
wherein the controller is configured to control the third valve to open the purge gas line subsequent to controlling the first valve to close the source gas line.

9. The substrate processing apparatus according to claim 8, further comprising:
a reactant gas supply including a reactant gas line connected to the process chamber, the reactant gas line configured to provide flow of a reactant gas; and
a fourth valve configured to selectively open and close the reactant gas line,
wherein, based upon the third valve being closed to the purge gas line, the controller is configured to control the fourth valve to open the reactant gas line.

10. The substrate processing apparatus according to claim 9, wherein, based upon the fourth valve being closed to the reactant gas line, the controller is configured to control the third valve to open the purge gas line and control the second valve to open the carrier gas line.

11. The substrate processing apparatus according to claim 1, further comprising:
a carrier gas box configured to store the carrier gas;
a first pressure sensor inside the canister; and
a second pressure sensor inside the carrier gas box,
wherein the controller is configured to calculate a concentration of the mixed gas based on an internal pressure value of the canister obtained by the first pressure sensor and an internal pressure value of the carrier gas box obtained by the second pressure sensor.

12. The substrate processing apparatus according to claim 11, wherein the controller is configured to control the first valve or the second valve based on the concentration of the mixed gas.

13. The substrate processing apparatus according to claim 1,
wherein the accommodation space is configured to accommodate a solid precursor or a liquid precursor, and
the canister is configured to generate the precursor gas by sublimating the solid precursor or vaporizing the liquid precursor.

14. The substrate processing apparatus according to claim 13, wherein the canister includes a heater configured to heat the solid precursor or the liquid precursor.

15. A substrate processing apparatus, comprising:
a process chamber for processing a substrate;
a carrier gas supply including a carrier gas box configured to store a carrier gas and a carrier gas line connected to the carrier gas box, the carrier gas line is configured to provide flow of the carrier gas;
a precursor gas supply including a canister configured to generate a precursor gas, and a source gas line configured to provide flow of a mixed gas of the carrier gas and the precursor gas, the source gas line connecting the canister and the process chamber; and
a valve on the source gas line and configured to control flow of the mixed gas to the process chamber.

16. The substrate processing apparatus according to claim 15, further comprising a controller configured to control the valve to close the source gas line to isolate the mixed gas in the precursor gas supply.

17. The substrate processing apparatus according to claim 16, further comprising a concentration sensor on the source gas line and configured to measure a concentration of the mixed gas,
wherein the controller is configured to control the valve based on the concentration of the mixed gas.

18. The substrate processing apparatus according to claim 16, wherein, based upon a predetermined time that elapses after the valve closes the source gas line, the controller is configured to control the valve to open the source gas line.

19. The substrate processing apparatus according to claim 15, wherein the canister comprises:
an accommodation space configured to accommodate a solid precursor or a liquid precursor; and
a heater outside the accommodation space, wherein the heater is configured to heat inside of the accommodation space.

20. A substrate processing apparatus, comprising:
a process chamber for processing a substrate;
a carrier gas supply including a carrier gas box configured to store a carrier gas and a carrier gas line connected to the carrier gas box, the carrier gas line is configured to provide flow of the carrier gas;
a precursor gas supply including a canister configured to generate a precursor gas, and a source gas line configured to provide flow of a mixed gas of the carrier gas and the precursor gas, wherein the source gas line connects the canister and the process chamber;
a first valve configured to selectively open and close the source gas line;
a second valve configured to selectively open and close the carrier gas line;
a concentration sensor disposed on the source gas line and configured to measure a concentration of the mixed gas; and
a controller configured to control the first valve or the second valve based on the concentration of the mixed gas measured by the concentration sensor,
wherein, based on the concentration of the mixed gas being less than a set concentration, the controller is configured to control the second valve to open the carrier gas line.
